(19) United States
(12) Patent Application Publication
(10) Pub. No.: US 2014/0231993 A1
(43) Pub. Date: Aug. 21, 2014

(54) PACKAGE-ON-PACKAGE STRUCTURES

(71) Applicant: Marvell World Trade Ltd., St. Michael (BB)

(72) Inventor: Huahung Kao, San Jose, CA (US)

(73) Assignee: Marvell World Trade Ltd., St. Michael (BB)

(21) Appl. No.: 14/184,986

(22) Filed: Feb. 20, 2014

Related U.S. Application Data
(60) Provisional application No. 61/767,337, filed on Feb. 21, 2013.

(51) Int. Cl. H01L 23/00; H01L 25/18; H01L 25/065

(52) U.S. Cl. CPC H01L 24/14; H01L 24/17; H01L 25/0657; H01L 25/18
USPC 257/738

(57) ABSTRACT

Embodiments of the present disclosure provide a first package configured to be coupled to a second package, wherein the first package comprises: a ball grid array substrate; a die coupled to the ball grid array substrate; two rows of ball pads arranged around a periphery of the ball grid array substrate, wherein the ball pads of the two rows of ball pads are configured to receive solder balls to couple the first package to the second package, wherein an outer row of the two rows of ball pads comprises at least some ball pads configured as a first type of ball pad, wherein an inner row of the two rows of ball pads comprises at least some ball pads configured as a second type of ball pad, wherein the first type of ball pad is different than the second type of ball pad.

### CROSS REFERENCE TO RELATED APPLICATIONS

This claims priority to U.S. Provisional Patent Application No. 61/767,337, filed Feb. 21, 2013, the entire specification of which is hereby incorporated by reference in its entirety.

### TECHNICAL FIELD

Embodiments of the present disclosure relate to package on package (POP) structures, and more particularly to packaging arrangements that include traces extending between ball pads.

### BACKGROUND

Typically, with many multi-chip packaging arrangements, a packaging arrangement is arranged in one of either a package-on-package (PoP) arrangement, or a multi-chip module (MCM) arrangement. These packaging arrangements tend to be fairly thick (e.g., approximately 1.7 millimeters to 2.0 millimeters).

A package-on-package packaging arrangement may include an integrated circuit that combines two or more packages on top of each other. For instance, a package-on-package packaging arrangement may be configured with two or more memory device packages. A package-on-package packaging arrangement may also be configured with mixed logic-memory stacking that includes logic in a bottom package and memory in a top package or vice versa.

A package-on-package packaging arrangement generally includes ball pads on a top side of a bottom package and ball pads on a bottom side of a top package. Solder balls are utilized to couple the top package to the bottom package via the ball pads. Generally, depending upon the type and size of the ball pads, space for traces that run between the ball pads can be limited. In other words, metal of adjacent ball pads can inhibit the number of traces that can be routed between the adjacent bond pads.

### SUMMARY

In various embodiments, the present disclosure provides a first package configured to be coupled to a second package, wherein the first package comprises a ball grid array substrate; a die coupled to the ball grid array substrate; two rows of ball pads arranged around a periphery of the ball grid array substrate, wherein the ball pads of the two rows of ball pads are configured to receive solder balls to couple the first package to the second package, wherein an outer row of the two rows of ball pads comprises at least some ball pads configured as a first type of ball pad, wherein an inner row of the two rows of ball pads comprises at least some ball pads configured as a second type of ball pad, wherein the first type of ball pad is different than the second type of ball pad, and wherein the die is configured as one of (i) a logic device or (ii) memory.

In various embodiments, the present disclosure also provides a package on package arrangement comprising: (A) a first package comprising (i) a ball grid array substrate, (ii) a first die coupled to the ball grid array substrate, and (iii) two rows of ball pads arranged around a periphery of the ball grid array substrate, wherein the ball pads of the two rows of ball pads are configured to receive solder balls to couple the first package to the second package, wherein an outer row of the two rows of ball pads comprises at least some ball pads configured as a first type of ball pad, wherein an inner row of the two rows of ball pads comprises at least some ball pads configured as a second type of ball pad, wherein the first type of ball pad is different than the second type of ball pad, and wherein the first die is configured as one of (i) a logic device or (ii) memory; and (B) a second package coupled to the first package, wherein the second package comprises a second die, wherein the second die is configured as one of (i) a logic device or (ii) memory, and wherein the first package and the second package are coupled to one another via solder balls at the two rows of ball pads arranged around the periphery of the first package.

### BRIEF DESCRIPTION OF THE DRAWINGS

Embodiments of the present disclosure will be readily understood by the following detailed description in conjunction with the accompanying drawings. To facilitate this description, like reference numerals designate like structural elements. Embodiments herein are illustrated by way of example and not by way of limitation in the figures of the accompanying drawings.

FIG. 1A schematically illustrates an example package on package packaging arrangement that includes an example die arrangement of a die-down flipped PoP structure.

FIG. 1B schematically illustrates another example package on package packaging arrangement.

FIG. 2A illustrates a portion of package on package packaging arrangement with a top package coupled to a bottom package.

FIG. 2B illustrates a top view of a solder mask defined ball pad.

FIG. 2C illustrates a top view of a non solder mask defined ball pad

FIGS. 3A-3C illustrate examples of an amount of spacing between metal pads of the various types of ball pads.

FIG. 4 illustrates an example of a map for ball pad arrangement for bottom packages of a package on package packaging arrangement.

FIG. 5 illustrates an example of a portion 500 of a bottom package with metal traces interspersed between ball pads.

### DETAILED DESCRIPTION

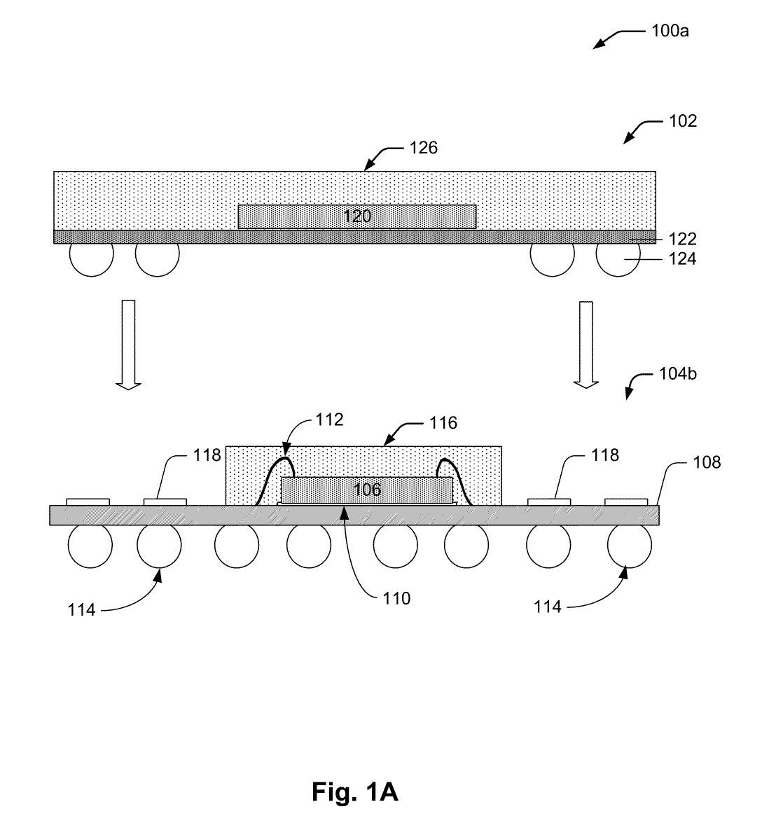

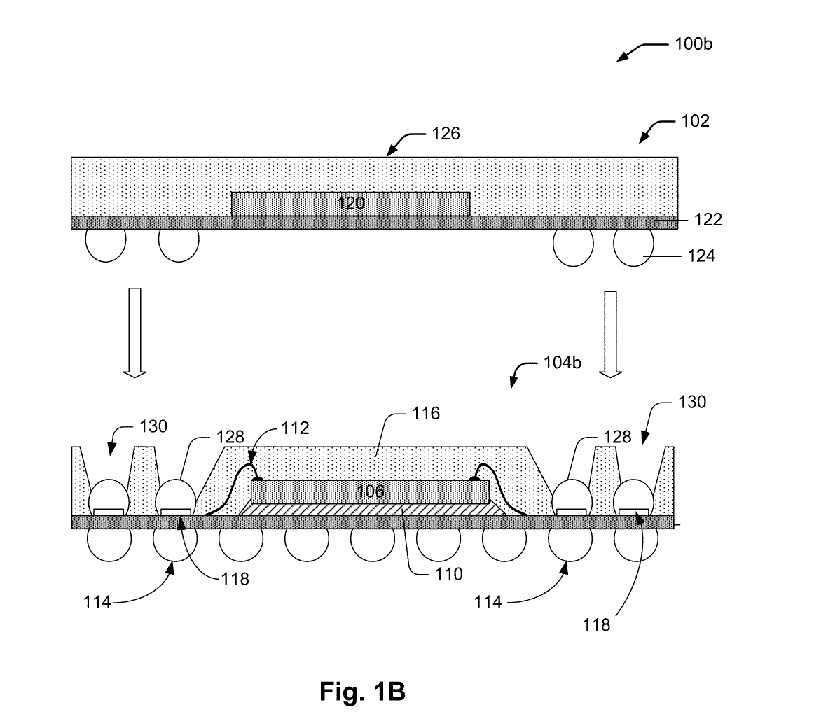

FIG. 1A illustrates an example package-on-package packaging arrangement 100a that includes a top package 102a and a bottom package 104a. As can be seen, the bottom package 104a includes a die 106 attached to a ball grid array substrate 108 via an adhesive 110. The die 106 is coupled to the ball grid array substrate 108 via a wirebonding process with wires 112. The die 106 can alternatively be flip chip attached to the ball grid array substrate 108. Solder balls 114 are provided for coupling the packaging arrangement 100 to another substrate (not illustrated) such as, for example, a printed circuit board (PCB). An enclosure 116, generally in the form of an encapsulant or molding material, is included around the die 106. Ball pads 118 are provided for receiving solder balls to couple the top package 102a to the bottom package 104.

The top package 102a includes a die 120 coupled to a substrate 122. Solder balls 124 are provided to couple the top package 102a to the bottom package 104a via ball pads 118. The top package 102a may include an enclosure 126, generally in the form of an encapsulant or molding material, if desired. One or both of the top package 102a and/or the bottom package 104a may include additional layers (not illustrated).

FIG. 1B illustrates another example of a packaging arrangement 100b where the bottom package 104b has been created with a Mold-Array-Process (MAP). The bottom package 104b is similar to the bottom package 104a of FIG. 1 and includes the encapsulant or molding material 116 along the length of the bottom package 104b. The encapsulant 116 is generally etched to expose solder balls 128 within openings 130. Alternatively, the encapsulant 116 is etched and then solder balls 128 are deposited within the openings 130. The solder balls 128 engage ball pads 118. The top package 102b includes a die 120 coupled to a substrate 122. Solder balls 124 are provided to engage the solder balls 128 via a reflow process to couple the top package 102 to the bottom package 104 via ball pads 118. The top package 102b may include an enclosure 126, generally in the form of an encapsulant or molding material, if desired. One or both of the top package 102b and/or the bottom package 104b may include additional layers (not illustrated).

In accordance with various embodiments, the die 120 of the top packages 102a, 102b is a memory device and, in accordance with an embodiment, the die 120 is a mobile double data rate (mDDR) synchronous dynamic random access memory (DRAM) for mobile devices. Mobile DDR is also known as low power DDR. However, other types of memory devices may be utilized, including but not limited to a double data rate synchronous dynamic random-access memory (DDR SDRAM), a dynamic random access memory (DRAM), a NOR or a NAND Flash memory, a static random-access memory (SRAM), and the like. Additionally, the top packages 102a, 102b may include multiple dies if desired.

In accordance with another embodiment, the top packages 102a, 102b with the die 120 are directed towards application-specific products and, in accordance with an embodiment, the die 120 may represent application-specific integrated circuits (ASICs) for a mobile device. The die may also be a logic device configured as one or more processors, one or more systems on a chip, etc. As previously noted, the top packages 102a, 102b may include multiple dies if desired.

In accordance with various embodiments, the die 106 of the bottom packages 104a, 104b may be a memory device, such as a mobile double data rate (mDDR) synchronous dynamic random access memory (DRAM) for mobile devices. Other types of memory devices may be utilized, including but not limited to a double data rate synchronous dynamic random-access memory (DDR SDRAM), a dynamic random access memory (DRAM), a NOR or a NAND Flash memory, a static random-access memory (SRAM), and the like. In accordance with another embodiment, the die 106 may be a logic device configured as one or more processors, one or more systems on a chip, etc. in order to create a mixed logic-memory stacking that includes logic on the bottom packages 104a, 104b and memory on the top packages 102a, 102b. The bottom packages 104a, 104b may include multiple dies if desired.

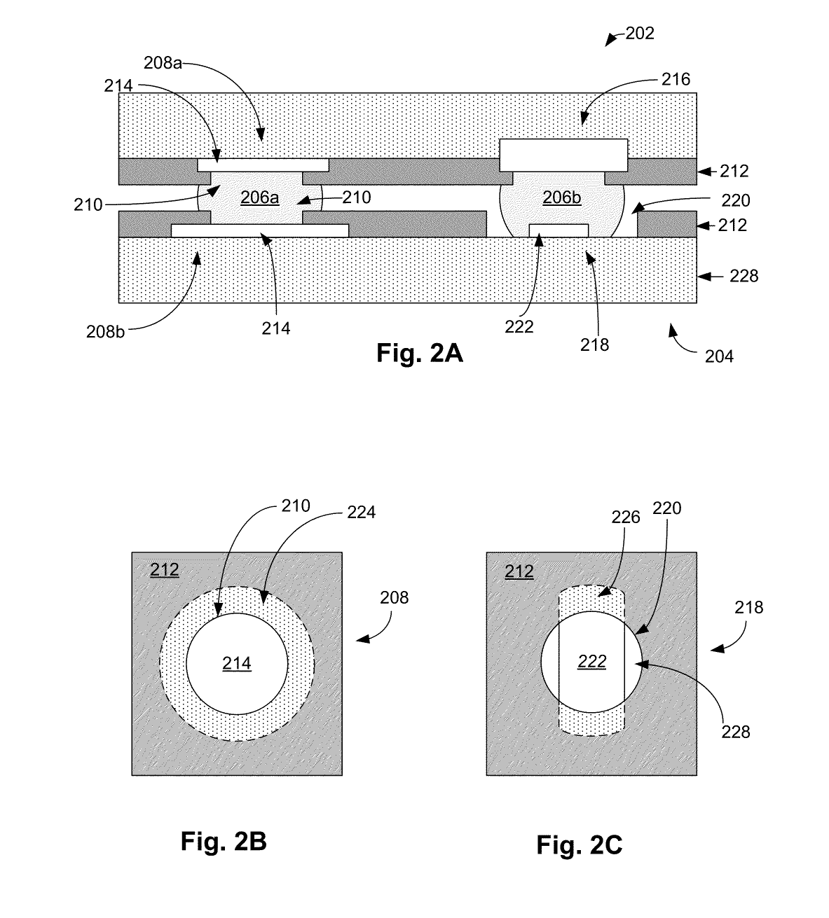

FIG. 2A illustrates a portion of a top package 202 coupled to a bottom package 204. The top package 202 can be similar to the top packages 102a, 102b of FIGS. 1A, and 1B. The bottom package 204 can be similar to the bottom packages 104a, 104b of FIGS. 1A, and 1B. In FIG. 2A, the top package 202 is coupled to the bottom package 204 via solder balls 206. A first solder ball 206a couples the top package 202 to the bottom package 204 utilizing solder mask defined (SMD) ball pads 208a, 208b for both the top package 202 and the bottom package 204. Thus, as can be seen, an opening 210 within a solder mask layer 212 over metal 214 of the SMD ball pads 208 is smaller than the total amount of metal 214 of the SMD ball pads 208.

A second solder ball 206b couples the top package 202 to the bottom package 204 with an SMD ball pad 216 for the top package 202 and a non-solder mask defined (NSMD) ball pad 218 for the bottom package 204. Thus, as can be seen, an opening 220 within the solder mask layer 212 over metal 222 of the NSMD bond pad 218 is larger than the total amount of metal 222 of the NSMD ball pad 218.

FIG. 2B illustrates a top view of the SMD ball pads 208, corresponding to SMD ball pads 208a, 208b, 216. FIG. 2C illustrates a top view of the NSMD ball pad 218.

As can be seen in FIG. 2B, the SMD ball pads 208 are defined by the opening 210 in the solder mask layer 212 that exposes the metal 214 below the solder mask layer 212. Thus, some of the metal 214 of the SMD ball pads 208 is still covered by the solder mask layer 212 as indicated by 224.

As can be seen in FIG. 2C, the NSMD ball pad 218 is defined by the opening 220 in the solder mask layer 212 that exposes the metal 222 below solder mask layer 212. Some of the solder mask layer 212 still covers part of the metal 222 of the NSMD ball pad 218, as indicated by 226. The opening 220 also exposes a portion of a ball grid array substrate 228, corresponding to the ball grid array substrate 108 of FIGS. 1A and 1B, along the sides of the metal 222 within the NSMD ball pad 218. While the present disclosure has referred to NSMD ball pad 218 as being a non-solder mask defined ball pad, since some of the metal 222 of the NSMD ball pad 218 still remains under the solder mask layer 212, the NSMD ball pad 218 can also be referred to as a partial NSMD ball pad. Thus, as used herein, NSMD ball pads also include partial NSMD ball pads.

Thus, in order to create and define the SMD ball pad 208b and NSMD ball pad 218, a metallization process is performed. A metal layer (not illustrated) is deposited over the ball grid array substrate 228 via a metallization process. Portions of the metal layer are removed to define the metal portions 214, 222 within the ball pads 208b, 218, respectively. The solder mask layer 212 is then deposited over the metal layer. Portions of the solder mask layer 212 are then removed to create the openings 210, 220 thereby exposing some of the metal portions 214, 222. Thus, dependent upon the openings 210, 220 over the ball pads 208b, 218, the size of the ball pads 208b, 218 is defined.

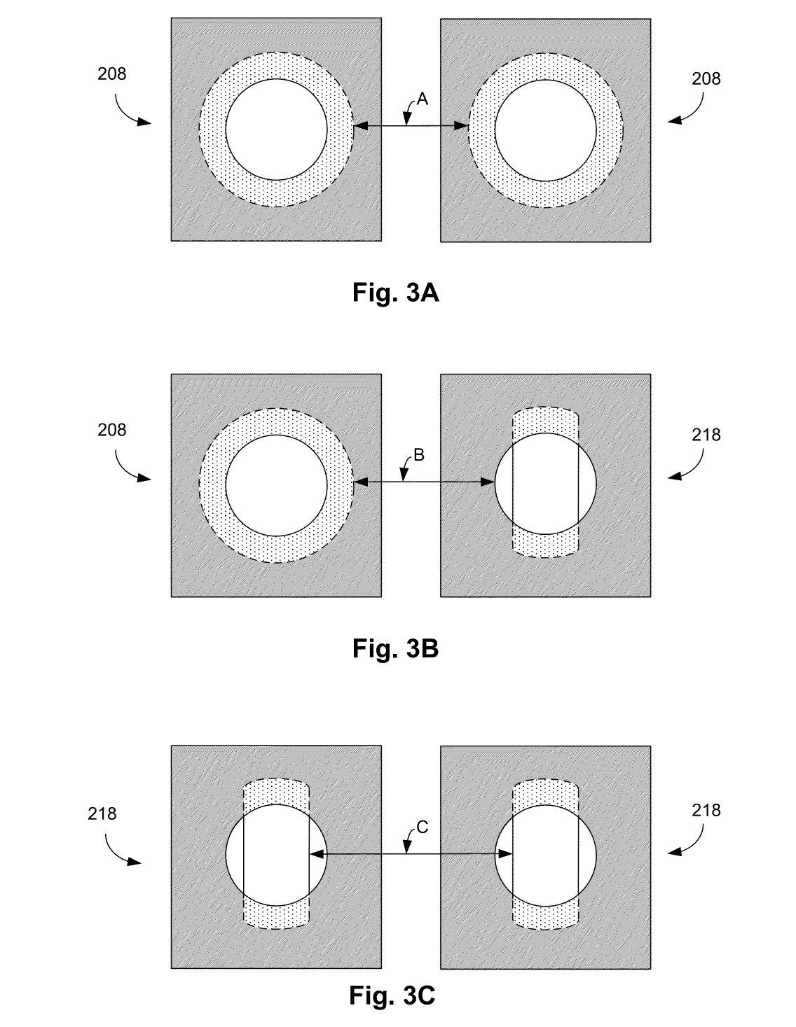

FIGS. 3A-3C illustrate examples of an amount of spacing between metal pads of the various types of ball pads. As can be seen in FIGS. 3A and 3C, two adjacent SMD ball pads 302 have a smaller amount of space within the ball grid substrate array between the metal portions of the SMD ball pads when compared to two adjacent NSMD ball pads 304, as illustrated by arrows A and C. The space between the metal portions of one SMD ball pad 302 and one NSMD ball pad 304 is represented by arrow B in FIG. 3B.

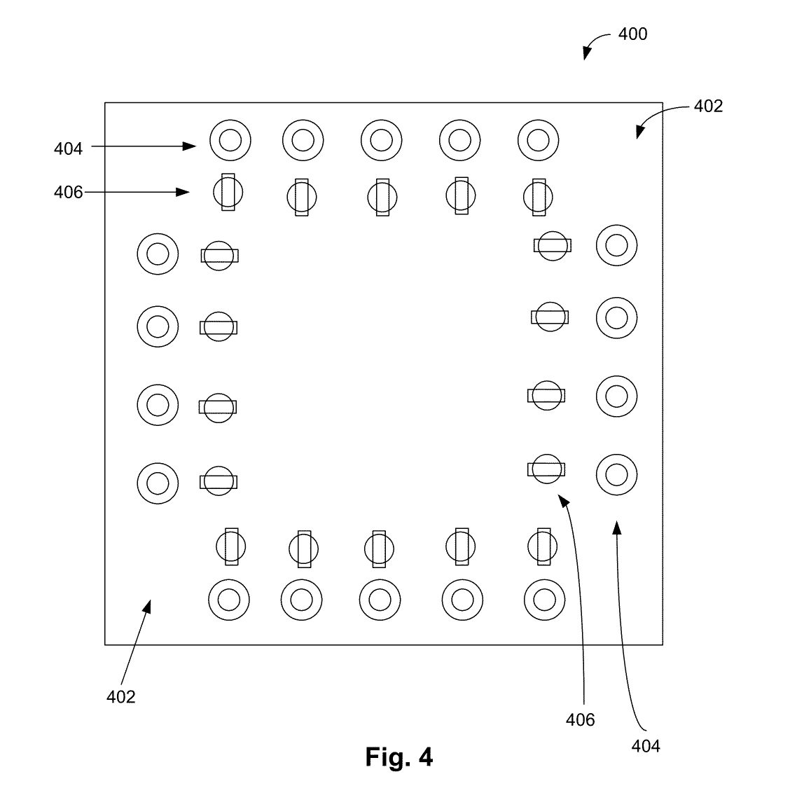

FIG. 4 illustrates an example of a map for ball pad arrangement for the bottom packages 104a, 104b. As can be seen, there are two rows 400 of ball pads that are arranged around a periphery of the bottom packages. An outer row 402 of the ball pads generally includes SMD ball pads. An inner row 404 of the two rows of ball pads generally includes NSMD ball pads. The rows can be mixed with respect to the types of ball pads if desired. Furthermore, both rows of ball pads may include only NSMD ball pads if desired.

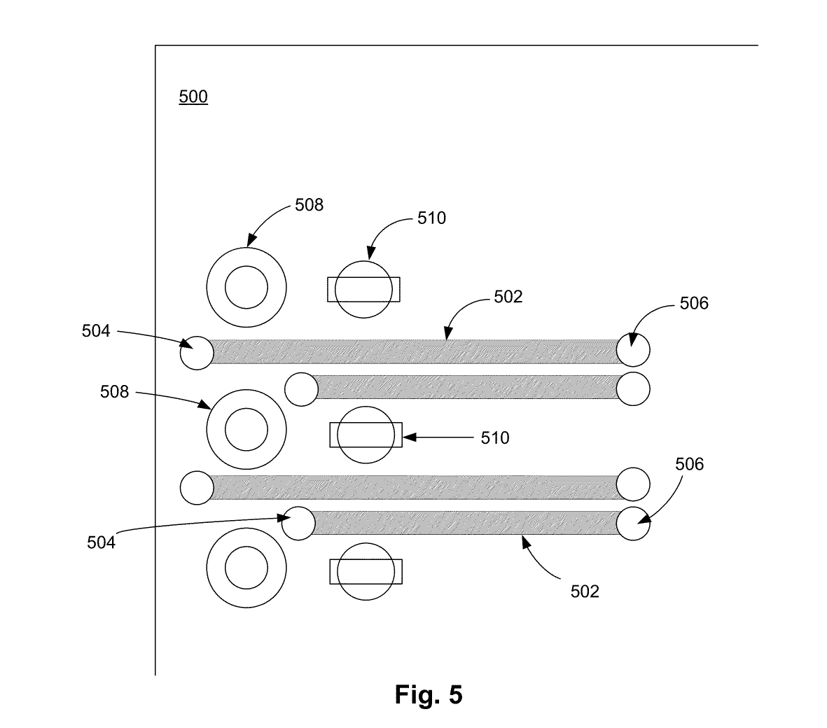

FIG. 5 illustrates an example of a portion 500 of a bottom package, which can be a portion of one of the bottom packages 104a, 104b. The portion 500 includes metal traces 502 from metal vias 504 to bond pads 506 for, for example, the die 106 of the bottom packages 104a, 104b of FIGS. 1A and 1B. As can be seen, in the embodiment illustrated in FIG. 5, adjacent ball pads 508 within the second or inner row of ball pads are NSMD ball pads. Thus, two metal traces 502 can extend between the two adjacent NSMD ball pads 508 due to the reduced amount of metal within the adjacent NSMD ball pads 508. As can be seen further in FIG. 5, only a single metal trace 502 can extend between two adjacent ball pads 510 in the outer row of ball pads since the ball pads 510 of the outer row are SMD ball pads. Thus, there is only room for a single metal trace 502 to extend between the metal portions of the NSMD ball pads 510. The vias 504 generally extend from the layer that includes the metal portions of the ball pads 508 and 510 to another metal layer (not illustrated) of the bottom package 500.

By utilizing at least a mix of SMD ball pads and NSMD ball pads, the overall space required for the ball pads is reduced due to the reduced amount of metal and thus, space is created for traces to extend between adjacent ball pads. Furthermore, use of SMD ball pads can result in a more robust solder joint on the SMD ball pads.

Further aspects of the present invention relates to one or more of the following clauses. In an embodiment, there is provided a first package configured to be coupled to a second package, wherein the first package comprises: a ball grid array substrate; a die coupled to the ball grid array substrate; two rows of ball pads arranged around a periphery of the ball grid array substrate, wherein the ball pads of the two rows of ball pads are configured to receive solder balls to couple the first package to the second package, wherein an outer row of the two rows of ball pads comprises at least some ball pads configured as a first type of ball pad, wherein an inner row of the two rows of ball pads comprises at least some ball pads configured as a second type of ball pad, wherein the first type of ball pad is different than the second type of ball pad, and wherein the die is configured as one of (i) a logic device or (ii) memory. In an embodiment, the first type of ball pad is a solder mask defined ball pad. In an embodiment, the second type of ball pad is a partial non solder mask defined ball pad. In an embodiment, the first type of ball pad is a solder mask defined ball pad. In an embodiment, the first package further comprises a first set of vias defined within the ball grid array substrate and interspersed among the ball pads; a second set of vias defined within the ball grid array substrate and interspersed among the ball pads; a first set of traces extending within the ball grid array substrate from the first set of vias to bond pads for the die that are located on the ball grid array substrate; and a second set of traces extending within the ball grid array substrate from the second set of vias to bond pads for the die that are located on the ball grid array substrate, wherein a first trace of the first set of traces and a second trace of the second set of traces extend substantially parallel to one another between two adjacent ball pads within the inner row of ball pads of the two rows of ball pads, and wherein the two adjacent ball pads comprise partial non solder mask defined ball pads. In an embodiment, the die is configured as a logic device. In an embodiment, the die is configured as memory. In an embodiment, the die is wirebonded to the ball grid array substrate. In an embodiment, the die is flip-chip attached to the ball grid array substrate.

In an embodiment, there is also provided a package on package arrangement comprising (A) a first package comprising (i) a ball grid array substrate, (ii) a first die coupled to the ball grid array substrate, and (iii) two rows of ball pads arranged around a periphery of the ball grid array substrate, wherein the ball pads of the two rows of ball pads are configured to receive solder balls to couple the first package to the second package, wherein an outer row of the two rows of ball pads comprises at least some ball pads configured as a first type of ball pad, wherein an inner row of the two rows of ball pads comprises at least some ball pads configured as a second type of ball pad, wherein the first type of ball pad is different than the second type of ball pad, and wherein the first die is configured as one of (i) a logic device or (ii) memory; and (B) a second package coupled to the first package, wherein the second package comprises a second die, wherein the second die is configured as one of (i) a logic device or (ii) memory, wherein the first package and the second package are coupled to one another via solder balls at the two rows of ball pads arranged around the periphery of the first package. In an embodiment, the first type of ball pad is a solder mask defined ball pad. In an embodiment, the second type of ball pad is a partial non solder mask defined ball pad. In an embodiment, the first type of ball pad is a solder mask defined ball pad. In an embodiment, the package on package arrangement further comprises: a first set of vias defined within the ball grid array substrate and interspersed among the ball pads; a second set of vias defined within the ball grid array substrate and interspersed among the ball pads; a first set of traces extending within the ball grid array substrate from the first set of vias to bond pads for the first die that are located on the ball grid array substrate; and a second set of traces extending within the ball grid array substrate from the second set of vias to bond pads for the first die that are located on the ball grid array substrate, wherein a first trace of the first set of traces and a second trace of the second set of traces extend substantially parallel to one another between two adjacent ball pads within the inner row of ball pads of the two rows of ball pads, and wherein the two adjacent ball pads comprise partial non solder mask defined ball pads. In an embodiment, the first die is configured as a logic device; and the second die is configured as memory. In an embodiment, the first die is configured as memory; and the second die is configured as a logic device. In an embodiment, the first die is wirebonded to the ball grid array substrate. In an embodiment, the first die is flip-chip attached to the ball grid array substrate. In an embodiment, the first type of ball pad is a solder mask defined ball pad. In an embodiment, the second type of ball pad is a partial non solder mask defined ball pad. In an embodiment, the first type of ball pad is a solder mask defined ball pad. In an embodiment, the package on package arrangement further comprises: a first set of vias defined within the ball grid array substrate and interspersed among the ball pads; a second set of vias defined within the ball grid array substrate and interspersed among the ball pads; a first set of traces extending within the ball grid array substrate from the first set of vias to bond pads for the first die that are located on the ball grid array substrate; and a second set of traces extending within the ball grid array substrate from the second set of vias to bond pads for the first die that are located on the ball grid array substrate, wherein a first trace of the first set of traces and a second trace of the second set of traces extend substantially parallel to one another between two adjacent ball pads within the inner row of ball pads of the two rows of ball pads, and wherein the two adjacent ball pads comprise partial non solder mask defined ball pads. In an embodiment, the first die is configured as a logic device; and the second die is configured as memory. In an embodiment, the first die is configured as memory; and the second die is configured as a logic device. In an embodiment, the first die is wirebonded to the ball grid array substrate. In an embodiment, the first die is flip-chip attached to the ball grid array substrate.

The description may use perspective-based descriptions such as up/down, over/under, and/or, or top/bottom. Such descriptions are merely used to facilitate the discussion and are not intended to restrict the application of embodiments described herein to any particular orientation.

For the purposes of the present disclosure, the phrase “A/B” means A or B. For the purposes of the present disclosure, the phrase “A and/or B” means “(A), (B), or (A and B).” For the purposes of the present disclosure, the phrase “at least one of A, B, and C” means “(A), (B), (C), (A and B), (A and C), (B and C), or (A, B and C).” For the purposes of the present disclosure, the phrase “(A)B” means “(B) or (AB)” that is, A is an optional element.

Various operations are described as multiple discrete operations in turn, in a manner that is most helpful in understanding the claimed subject matter. However, the order of description should not be construed as to imply that these operations are necessarily order-dependent. In particular, these operations may not be performed in the order of presentation. Operations described may be performed in a different order than the described embodiment. Various additional operations may be performed and/or described operations may be omitted in additional embodiments.

The description uses the phrases “in an embodiment,” “in embodiments,” or similar language, which may each refer to one or more of the same or different embodiments. Furthermore, the terms “comprising,” “including,” “having,” and the like, as used with respect to embodiments of the present disclosure, are synonymous.

The terms chip, integrated circuit, monolithic device, semiconductor device, die, and microelectronic device are often used interchangeably in the microelectronics field. The present invention is applicable to all of the above as they are generally understood in the field.

Although certain embodiments have been illustrated and described herein, a wide variety of alternate and/or equivalent embodiments or implementations calculated to achieve the same purposes may be substituted for the embodiments illustrated and described without departing from the scope of the present disclosure. This disclosure is intended to cover any adaptations or variations of the embodiments discussed herein. Therefore, it is manifestly intended that embodiments described herein be limited only by the claims and the equivalents thereof.

What is claimed is:

1. A first package configured to be coupled to a second package, wherein the first package comprises:
a ball grid array substrate;
a die coupled to the ball grid array substrate;
two rows of ball pads arranged around a periphery of the ball grid array substrate,
wherein the ball pads of the two rows of ball pads are configured to receive solder balls to couple the first package to the second package,
wherein an outer row of the two rows of ball pads comprises at least some ball pads configured as a first type of ball pad,
wherein an inner row of the two rows of ball pads comprises at least some ball pads configured as a second type of ball pad,
wherein the first type of ball pad is different than the second type of ball pad, and
wherein the die is configured as one of (i) a logic device or (ii) memory.

2. The first package of claim 1, wherein the first type of ball pad is a solder mask defined ball pad.

3. The first package of claim 1, wherein the second type of ball pad is a partial non solder mask defined ball pad.

4. The first package of claim 3, wherein the first type of ball pad is a solder mask defined ball pad.

5. The first package of claim 4, further comprising:
a first set of vias defined within the ball grid array substrate and interspersed among the ball pads;
a second set of vias defined within the ball grid array substrate and interspersed among the ball pads;
a first set of traces extending within the ball grid array substrate from the first set of vias to bond pads for the die that are located on the ball grid array substrate; and
a second set of traces extending within the ball grid array substrate from the second set of vias to bond pads for the die that are located on the ball grid array substrate,
wherein a first trace of the first set of traces and a second trace of the second set of traces extend substantially parallel to one another between two adjacent ball pads within the inner row of ball pads of the two rows of ball pads, and
wherein the two adjacent ball pads comprise partial non solder mask defined ball pads.

6. The first package of claim 1, wherein the die is configured as a logic device.

7. The first package of claim 1, wherein the die is configured as memory.

8. The first package of claim 1, wherein the die is wirebonded to the ball grid array substrate.

9. The first package of claim 1, wherein the die is flip-chip attached to the ball grid array substrate.

10. A package on package arrangement comprising:
a first package comprising
a ball grid array substrate,
a first die coupled to the ball grid array substrate, and
two rows of ball pads arranged around a periphery of the ball grid array substrate,
wherein the ball pads of the two rows of ball pads are configured to receive solder balls to couple the first package to the second package,
wherein an outer row of the two rows of ball pads comprises at least some ball pads configured as a first type of ball pad,
wherein an inner row of the two rows of ball pads comprises at least some ball pads configured as a second type of ball pad,
wherein the first type of ball pad is different than the second type of ball pad, and
wherein the first die is configured as one of (i) a logic device or (ii) memory; and
a second package coupled to the first package, wherein the second package comprises
a second die,
wherein the second die is configured as one of (i) a logic device or (ii) memory,
wherein the first package and the second package are coupled to one another via solder balls at the two rows of ball pads arranged around the periphery of the first package.

11. The package on package arrangement of claim 10, wherein the first type of ball pad is a solder mask defined ball pad.

12. The package on package arrangement of claim 10, wherein the second type of ball pad is a partial non solder mask defined ball pad.

13. The package on package arrangement of claim 12, wherein the first type of ball pad is a solder mask defined ball pad.

14. The package on package arrangement of claim 13, further comprising:
a first set of vias defined within the ball grid array substrate and interspersed among the ball pads;
a second set of vias defined within the ball grid array substrate and interspersed among the ball pads;
a first set of traces extending within the ball grid array substrate from the first set of vias to bond pads for the first die that are located on the ball grid array substrate; and
a second set of traces extending within the ball grid array substrate from the second set of vias to bond pads for the first die that are located on the ball grid array substrate,
wherein a first trace of the first set of traces and a second trace of the second set of traces extend substantially parallel to one another between two adjacent ball pads within the inner row of ball pads of the two rows of ball pads, and
wherein the two adjacent ball pads comprise partial non solder mask defined ball pads.

15. The package on package arrangement of claim 10, wherein:
the first die is configured as a logic device; and
the second die is configured as memory.

16. The package on package arrangement of claim 10, wherein:
the first die is configured as memory; and
the second die is configured as a logic device.

17. The package on package arrangement of claim 10, wherein the first die is wirebonded to the ball grid array substrate.

18. The package on package arrangement of claim 10, wherein the first die is flip-chip attached to the ball grid array substrate.
